(19) United States
(12) Patent Application Publication
(10) Pub. No.: US 2022/0148861 A1
(43) Pub. Date: May 12, 2022

(54) SUBSTRATE PROCESSING APPARATUS

(71) Applicant: Tokyo Electron Limited, Tokyo (JP)

(72) Inventors: Wataru SHIMIZU, Miyagi (JP); Ryoya ABE, Miyagi (JP); Tomoya UJIIE, Miyagi (JP)

(73) Assignee: Tokyo Electron Limited, Tokyo (JP)

(21) Appl. No.: 17/520,735

(22) Filed: Nov. 8, 2021

(30) Foreign Application Priority Data
Nov. 10, 2020 (JP) 2020-187398

(51) Int. Cl. H01J 37/32

(52) U.S. Cl. CPC H01J 37/32834

(57) ABSTRACT

A chamber is provided where an exhaust port for exhausting a gas in an inside thereof is formed thereon and substrate processing for a substrate is executed in the inside. A partition member partitions the inside of the chamber into a processing region where the substrate processing is executed and an exhaust region that leads to the exhaust port. The partition member is configured to include a plurality of plate-shaped members. The plurality of plate-shaped members are provided in such a manner that at least a part of each thereof is arranged obliquely at intervals in a side view from a side of a side surface of the chamber and an upper end part of each thereof is arranged so as to overlap with a lower end part of the plate-shaped member that is adjacent thereto in a top view from an upper side of the chamber.

### CROSS-REFERENCE TO RELATED APPLICATIONS

The present application claims priority to and incorporates by reference the entire contents of Japanese Patent Application No. 2020-187398 filed in Japan on Nov. 10, 2020.

### FIELD

The present disclosure relates to a substrate processing apparatus.

### BACKGROUND

Japanese Patent Application Publication No. 2016-063083 discloses a method where a partition member that is composed of two flat plates is arranged so as to execute partition between a processing region where plasma is produced and an exhaust region, so that particles do not scatter from the exhaust region to the processing region.

The present disclosure provides a technique that prevents or reduces penetration of particles that are generated in an exhaust region into a processing region and prevents or reduces degradation of an exhaust characteristic.

### SUMMARY

According to an aspect of a present disclosure, a substrate processing apparatus includes a chamber and a partition member. The chamber is provided where an exhaust port for exhausting a gas in an inside thereof is formed thereon and substrate processing for a substrate is executed in the inside. The partition member partitions the inside of the chamber into a processing region where the substrate processing is executed and an exhaust region that leads to the exhaust port. The partition member is configured to include a plurality of plate-shaped members. the plurality of plate-shaped members are provided in such a manner that at least a part of each thereof is arranged obliquely at intervals in a side view from a side of a side surface of the chamber and an upper end part of each thereof is arranged to overlap with a lower end part of the plate-shaped member that is adjacent thereto in a top view from an upper side of the chamber.

### BRIEF DESCRIPTION OF DRAWINGS

FIG. 1 is a schematic cross-sectional view that illustrates an example of a substrate processing apparatus according to an embodiment.

FIG. 2 is a diagram that illustrates an example of a plate-shaped member according to an embodiment.

FIG. 3 is a diagram that illustrates an example of arrangement of a plate-shaped member according to an embodiment.

FIG. 4 is a perspective view that illustrates an example of arrangement of a plate-shaped member according to an embodiment.

FIG. 5 is a diagram that illustrates an example of arrangement of a conventional partition member.

FIG. 6 is a perspective view that illustrates an example of arrangement of a conventional partition member.

FIG. 7 is a diagram that illustrates another example of a plate-shaped member according to an embodiment.

FIG. 8 is a diagram that illustrates another example of a plate-shaped member according to an embodiment.

FIG. 9 is a diagram that illustrates another example of a plate-shaped member according to an embodiment.

### DESCRIPTION OF EMBODIMENTS

Hereinafter, an embodiment of a substrate processing apparatus as disclosed in the present application will be explained in detail with reference to the drawings. Additionally, a disclosed substrate processing apparatus is not limited by the present embodiment.

In a substrate processing apparatus, particles that are generated in an exhaust region of a chamber may recoil and land on a substrate that is provided in a processing region so as to cause a defect or the like in a device that is formed on the substrate. As a method of solving thereof, a method has been proposed where a plurality of partition plates are arranged between an exhaust region where particles that are generated and a processing region. However, a gas flow for a conventional partition plate affects a conductance so as to degrade an exhaust characteristic.

Hence, a technique has been expected that prevents or reduces penetration of particles that are generated in an exhaust region into a processing region and prevents or reduces degradation of an exhaust characteristic.

### Embodiment

Apparatus Configuration

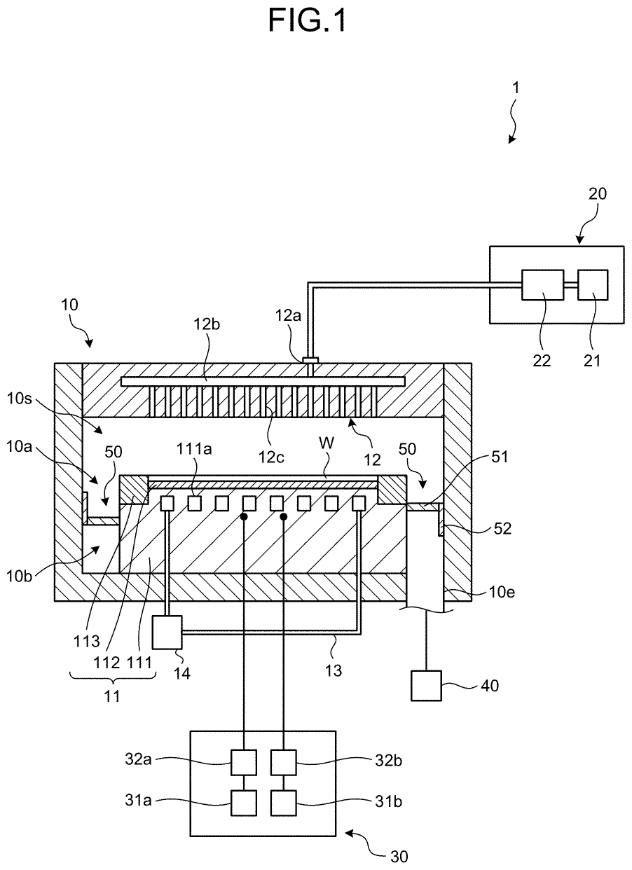

Next, an embodiment will be explained. First, a substrate processing apparatus 1 according to an embodiment will be explained. The substrate processing apparatus 1 executes substrate processing for a substrate. In an embodiment, a case where the substrate processing apparatus 1 is provided as a plasma processing apparatus and plasma processing as substrate processing is executed for a substrate will be explained as an example. FIG. 1 is a schematic cross-sectional view that illustrates an example of the substrate processing apparatus 1 according to an embodiment. In an embodiment, the substrate processing apparatus 1 includes a chamber 10, a gas supply unit 20, an RF (Radio Frequency) power supply unit 30, and an exhaust system 40. Furthermore, the substrate processing apparatus 1 includes a mounting table 11 and an upper electrode shower head 12.

A cylindrical space is formed inside the chamber 10. The mounting table 11 is provided inside the chamber 10. The mounting table 11 is formed into a cylindrical shape and is arranged in a lower region at a center in the chamber 10. The upper electrode shower head 12 is arranged above the mounting table 11 and is capable of functioning as a part of a top part (a ceiling) of the chamber 10.

The mounting table 11 is configured to support a substrate W such as a semiconductor wafer in a plasma processing space 10s where plasma processing is executed. In an embodiment, the mounting table 11 includes a lower electrode 111, an electrostatic chuck 112, and an edge ring 113. The electrostatic chuck 112 is arranged on the lower electrode 111 and is configured to support a substrate W on an upper surface of the electrostatic chuck 112. The edge ring 113 is arranged so as to surround a substrate W on an upper surface of a peripheral part of the lower electrode 111. The lower electrode 111 is composed of an electrically conductive metal, for example, aluminum or the like. The lower electrode 111 functions as a base that supports the electrostatic chuck 112 and the edge ring 113. The mounting table 11 may include a temperature adjustment module that is configured to adjust at least one of the electrostatic chuck 112 and a substrate W so as to be at a target temperature. A temperature adjustment module may include a heater, a flow channel, or a combination thereof. For example, a flow channel 111a for causing a temperature adjustment medium to flow thereon is formed inside the lower electrode 111. The flow channel 111a is formed over a whole area of a mounting region where a substrate W is mounted, according to the mounting region. A temperature adjustment medium such as a cooling medium or a heating medium flows on the flow channel 111a. For example, the flow channel 111a is connected to a chiller unit 14 through pipelines 13. The chiller unit 14 is capable of controlling a temperature of a cooling medium that is supplied therefrom. The substrate processing apparatus 1 is configured to circulate a cooling medium at a controlled temperature (for example, cooling water) from the chiller unit 14 to the flow channel 111a so as to be capable of controlling a temperature of the mounting table 11. Additionally, the substrate processing apparatus 1 may be configured to supply a heat-transfer gas to a side of a back surface of a substrate W or the edge ring 113 so as to be capable of controlling a temperature thereof. For example, a gas supply pipe for supplying a heat-transfer gas (a back side gas) such as a helium gas may be provided on a back surface of a substrate W so as to penetrate through the mounting table 11 or the like. A gas supply pipe is connected to a gas supply source. By such a configuration, a substrate W that is adsorbed and held on an upper surface of the mounting table 11 by the electrostatic chuck 112 is controlled so as to be at a predetermined temperature.

The upper electrode shower head 12 is configured to supply one or more processing gasses from the gas supply unit 20 to the plasma processing space 10s. In an embodiment, the upper electrode shower head 12 has a gas inlet 12a, a gas diffusion room 12b, and a plurality of gas outlets 12c. The gas inlet 12a is fluid-communicated with the gas supply unit 20 and the gas diffusion room 12b. The plurality of gas outlets 12c are fluid-communicated with the gas diffusion room 12b and the plasma processing space 10s. In an embodiment, the upper electrode shower head 12 is configured to supply one or more processing gasses from the gas inlet 12a to the plasma processing space 10s through the gas diffusion room 12b and the plurality of gas outlets 12c.

The gas supply unit 20 may include one or more gas sources 21 and one or more flow volume controllers 22. In an embodiment, the gas supply unit 20 is configured to supply one or more processing gasses from respectively corresponding gas sources 21 to the gas inlet 12a through respectively corresponding flow volume controllers 22. Each flow volume controller 22 may include, for example, a mass flow controller or a pressure-control-type flow volume controller. Moreover, the gas supply unit 20 may include one or more flow volume modulation devices that modulate, or pulse the flow volume of one or more processing gasses.

The RF power supply unit 30 is configured to supply RF power, for example, one or more RF signals to one or more electrodes such as the lower electrode 111, the upper electrode shower head 12, or both the lower electrode 111 and the upper electrode shower head 12. Thereby, plasma is produced from one or more processing gasses that are supplied to the plasma processing space 10s. Therefore, the RF power supply unit 30 is capable of functioning as at least a part of a plasma production unit that is configured to produce plasma from one or more processing gasses in a plasma processing chamber. In an embodiment, the RF power supply unit 30 includes two RF production units 31a, 31b and two matching circuits 32a, 32b. In an embodiment, the RF power supply unit 30 is configured to supply a first RF signal from a first RF production unit 31a to the lower electrode 111 through a first matching circuit 32a. For example, a first RF signal may have a frequency within a range of 27 MHz to 100 MHz.

Furthermore, in an embodiment, the RF power supply unit 30 is configured to supply a second RF signal from a second RF production unit 31b to the lower electrode 111 through a second matching circuit 32b. For example, a second RF signal may have a frequency within a range of 400 kHz to 13.56 MHz. Alternatively, a DC (Direct Current) pulse production unit may be used instead of the second RF production unit 31b.

Moreover, it is possible to consider another embodiment in the present disclosure although illustration thereof is omitted. For example, the RF power supply unit 30 may be configured to supply a first RF signal from an RF production unit to the lower electrode 111, supply a second RF signal from another production unit to the lower electrode 111, and supply a third RF signal from yet another RF production unit to the lower electrode 111. In addition, a DC voltage may be applied to the upper electrode shower head 12.

Also, moreover, in a variety of embodiments, pulse production or modulation of amplitude of one or more RF signals (that is, a first RF signal, a second RF signal, and/or the like) may be executed. Amplitude modulation may include pulse production of RF signal amplitude between an on-state and an off-state or between two or more different on-states.

An exhaust port 10e for exhausting a gas inside the chamber 10 is formed thereon. In the chamber 10 according to an embodiment, the mounting table 11 is arranged at a center thereof and the exhaust port 10e is singly provided at a position that is lower than a mounting surface of the mounting table 11 where a substrate W is mounted, around the mounting table 11. For example, the exhaust port 10e is provided on a bottom part of the chamber 10 that is provided as a periphery of the mounting table 11. The exhaust system 40 is capable of being connected to the exhaust port 10e that is provided on a bottom part of the chamber 10. The exhaust system 40 may include a pressure valve and a vacuum pump. A vacuum pump may include a turbo-molecular pump, a roughing pump, or a combination thereof.

On a side of a bottom part of the chamber 10, a partition member 50 is provided between the mounting table 11 and an inner wall of the chamber 10. An inside of the chamber 10 is partitioned into a processing region 10a where substrate processing such as plasma processing is executed and an exhaust region 10b that leads to the exhaust port 10e, by the partition member 50. The processing region 10a includes the plasma processing space 10s as described above and an upper space for the partition member 50 around the mounting table 11.

The partition member 50 is configured to include a plurality of plate-shaped members 51 and a support member 52. The support member 52 is provided so as to surround a periphery of the mounting table 11. For example, the support member 52 is provided on an inner side surface of the chamber 10 that faces a side surface of the mounting table 11. Additionally, the support member 52 may be provided on a side surface of the mounting table 11.

The plurality of plate-shaped members 51 are fixed on the support member 52 so as to be arranged around the mounting table 11. The support member 52 supports the plurality of plate-shaped members 51 that are fixed thereon. The plurality of plate-shaped members 51 are provided at respective intervals and at least a part of each thereof is arranged obliquely, in a side view from a side of a side surface of the chamber 10. Furthermore, the plurality of plate-shaped members 51 are arranged in such a manner that an upper end part 51a of each thereof overlaps with a lower end part of a plate-shaped member 51 that is adjacent thereto, in a top view from an upper side of the chamber 10. Additionally, the partition member 50 may be configured to fix the plurality of plate-shaped members 51 on an inner side surface of the chamber 10 or a side surface of the mounting table 11 without providing the support member 52 thereto.

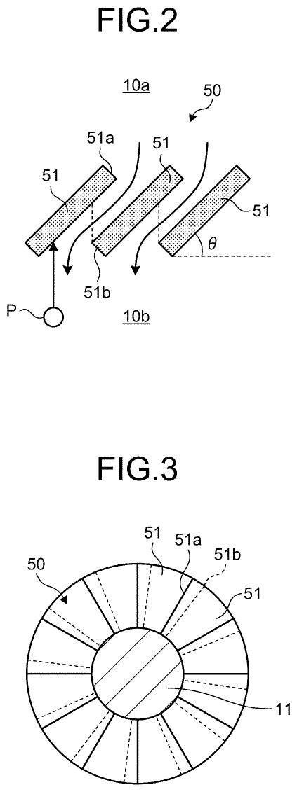

FIG. 2 is a diagram that illustrates an example of plate-shaped members 51 according to an embodiment. FIG. 2 is a diagram in a side view in a case where the plate-shaped members 51 are viewed from a side of a side surface of a chamber 10. Upward and downward directions in FIG. 2 are vertical directions, an upper side of the plate-shaped members 51 is a processing region 10a, and a lower side of the plate-shaped members 51 is an exhaust region 10b. Leftward and rightward directions in FIG. 2 are horizontal directions. Each of the plate-shaped members 51 is provided as a flat plate that is flat. The plate-shaped members 51 are arranged so as to be angled relative to a horizontal direction so that a whole thereof is oblique. The plate-shaped members 51 are arranged at intervals so as to provide gaps therebetween, so that it is possible for an exhaust gas to flow between respective plate-shaped members 51. It is preferable for an angle θ of the plate-shaped members 51 relative to a horizontal direction to be within a range of 15° to 60° where it is more preferable to be within a range of 30° to 45°. A plate-shaped member 51 is arranged in such a manner that an upper end part 51a thereof overlaps with a lower end part 51b of a plate-shaped member 51 that is adjacent thereto.

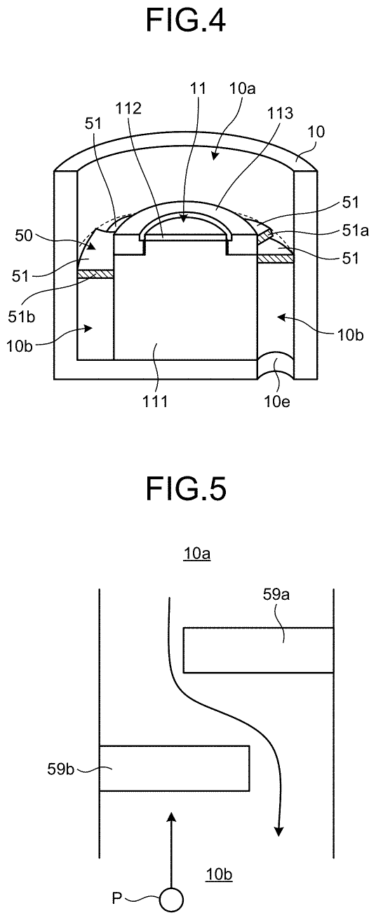

FIG. 3 is a diagram that illustrates an example of arrangement of plate-shaped members 51 according to an embodiment. FIG. 4 is a perspective view that illustrates an example of arrangement of plate-shaped members 51 according to an embodiment. FIG. 3 is a diagram in a top view in a case where the plate-shaped members 51 and a mounting table 11 are viewed from an upper side of a chamber 10. In FIG. 3, twelve plate-shaped members 51 are arranged so as to surround a periphery of the mounting table 11 with a circular shape. Additionally, a number of the plate-shaped members is not limited to twelve and any number may be provided. For example, a number of the plate-shaped members 51 may be eight or twenty-four. Each plate-shaped member 51 is arranged in such a manner that an upper end part 51a thereof overlaps with a lower end part 51b of a plate-shaped member 51 that is adjacent thereto and the lower end part 51b of each plate-shaped member 51 that is adjacent thereto overlaps with the lower end part 51a thereof, so that the lower end part 51b is covered with the upper end part 51a of the plate-shaped member 51 that is adjacent thereto. Thereby, a state is provided where it is not possible to view gaps between respective plate-shaped members 51 in a top view, so that it is possible to prevent or reduce penetrating of particles P that are generated in an exhaust region 10b into a processing region 10a.

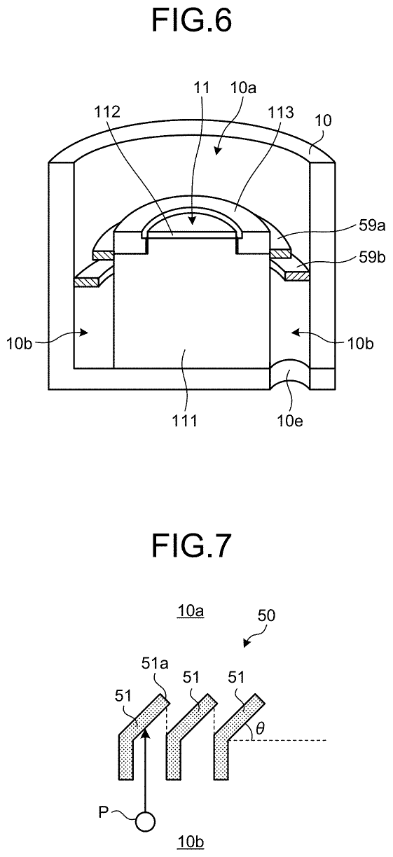

Herein, for comparison, an example of arrangement of a conventional partition member will be explained. FIG. 5 is a diagram that illustrates an example of arrangement of a conventional partition member. FIG. 6 is a perspective view that illustrates an example of arrangement of a conventional partition member. In FIG. 5 and FIG. 6, two flat plates 59a, 59b as a partition member are arranged between a processing region 10a and an exhaust region 10b. A conventional partition member is provided in a state where regions of the flat plates 59a, 59b overlap and it is not possible to view a gap between the flat plates 59a, 59b in a top view, so that it is possible to prevent or reduce penetrating of particles P that are generated in the exhaust region 10b into the processing region 10a. However, in a conventional partition member, a periphery of a mounting table 11 is covered with an upper flat plate 59a so as to decrease a surface area of an opening part where an exhaust gas flows, increase a conductance, and degrade an exhaust characteristic.

On the other hand, in an partition member 50 according to an embodiment, respective plate-shaped members 51 are obliquely arranged at intervals, so that it is possible for an exhaust gas to flow between respective plate-shaped members 51 and hence it is possible to prevent or reduce degradation of an exhaust characteristic. Furthermore, the partition member 50 according to an embodiment is provided in a state where it is not possible to view gaps between respective plate-shaped members 51 in a top view, so that it is possible to prevent or reduce penetrating of particles P that are generated in an exhaust region 10b into a processing region 10a. That is, it is possible for a plate-shaped members 51 according to an embodiment to prevent or reduce penetration of particles P that are generated in the exhaust region 10b into the processing region 10a and prevent or reduce degradation of an exhaust characteristic.

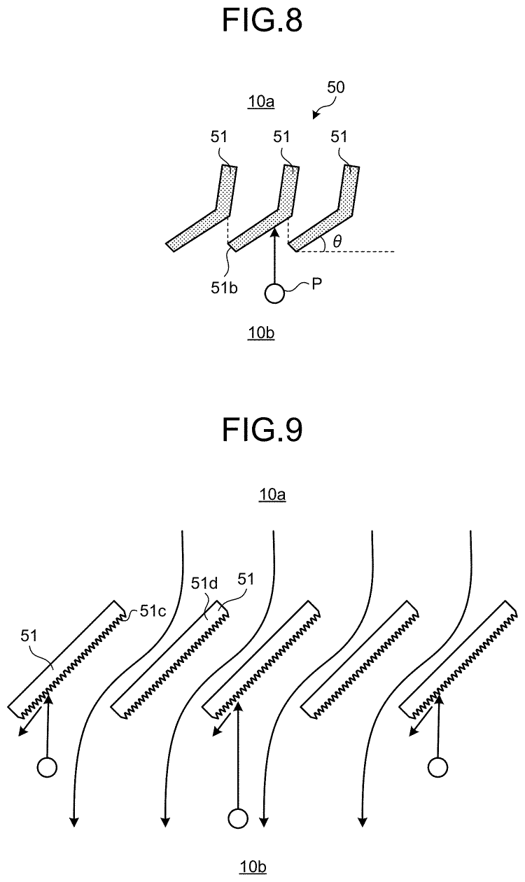

Although FIG. 2 has explained a case where the plate-shaped members 51 are provided as flat plates that are flat, a shape of the plate-shaped members 51 are not limited thereto. The plate-shaped members 51 may be provided as a curved plates. FIG. 7 and FIG. 8 are diagrams that illustrate another example of a plate-shaped members 51 according to an embodiment. FIG. 7 and FIG. 8 are diagrams in a side view in a case where the plate-shaped members 51 are viewed from a side of a side surface of a chamber 10. Upward and downward directions in FIG. 7 and FIG. 8 are vertical directions, an upper side of the plate-shaped members 51 is a processing region 10a, and a lower side of the plate-shaped members 51 is an exhaust region 10b. Leftward and rightward directions in FIG. 7 and FIG. 8 are horizontal directions. Each plate-shaped member 51 is provided as a plate that is curved near a center thereof. In FIG. 7, each plate-shaped member 51 is arranged in such a manner that a side of the processing region 10a is more oblique than a side of the exhaust region 10b. In FIG. 8, each plate-shaped member 51 is arranged in such a manner that a side of the exhaust region 10b is more oblique than a side of the processing region 10a. In FIG. 7, it is preferable for an angle θ of upper parts of the plate-shaped members 51 relative to a horizontal direction to be within a range of 15° to 60° where it is more preferable to be within a range of 30° to 45°. In FIG. 8, it is preferable for an angle θ of lower parts of the plate-shaped members 51 relative to a horizontal direction to be within a range of 15° to 60° where it is more preferable to be within a range of 30° to 45°. A plate-shaped member 51 is arranged in such a manner that an upper end part 51a thereof overlaps with a lower end part 51b of a plate-shaped member 51 that is adjacent thereto. For example, in FIG. 7, a plate-shaped member 51 is arranged in such a manner that an upper end part 51a thereof overlaps with a plate-shaped member 51 that is adjacent thereto. In FIG. 8, a plate-shaped member 51 is arranged in such a manner that a lower end part 51b thereof overlaps with a plate-shaped member 51 that is adjacent thereto. Also in cases of FIG. 7 and FIG. 8, it is possible for a plate-shaped members 51 to prevent or reduce penetration of particles P that are generated in the exhaust region 10b into the processing region 10a and prevent or reduce degradation of an exhaust characteristic. Furthermore, as illustrated in FIG. 8, a plate-shaped members 51 are arranged in such a manner that a side of the exhaust region 10b is more oblique than a side of the processing region 10a, so that a swirling flow is generated along a circumferential direction of a mounting table 11 on a side of the exhaust region 10b. As a swirling flow is generated in a circumferential direction of the mounting table 11, it is possible to collect a deposition that is deposited by a gas that is included in an exhaust gas, on a side of the mounting table 11. Additionally, a curved part is not limited to a vicinity of a center of a plate-shaped member 51 as illustrated in FIG. 7 and FIG. 8, and further, is not limited to a single part. For example, it may have two or more or a plurality of curved parts. Furthermore, a linearly curved one as illustrated in FIG. 7 and FIG. 8 is not limiting where, for example, a curvilinearly curved shape may be provided.

A state of a surface of a plate-shaped member 51 may be changed between a surface on a side of the exhaust region 10b and a surface on a side of the processing region 10a. For example, a plate-shaped member 51 may include an absorption mechanism that absorbs a kinetic energy of particles P from a side of the exhaust region 10b, on a surface on a side of the exhaust region 10b. Furthermore, a surface treatment that decreases a kinetic frictional resistance may be applied to a surface of a plate-shaped member 51 on a side of the processing region 10a. FIG. 9 is a diagram that illustrates another example of a plate-shaped members 51 according to an embodiment. recesses and protrusions as an absorption mechanism are provided on a surface 51c of a plate-shaped member 51 on a side of an exhaust region 10b. Thereby, particles P that come from a side of the exhaust region 10b collide with recesses and protrusions and a kinetic energy of the particles P is absorbed, so that it is possible to prevent or reduce penetration of the particles P into a processing region 10a. Additionally, any absorption mechanism may be provided as long as a kinetic energy of a particles P is absorbed. For example, a member with a material that absorbs particles P as an absorption mechanism may be attached to the surface 51c on a side of the exhaust region 10b.

Furthermore, mirror finishing as a surface treatment is applied to a surface 51d of a plate-shaped member 51 on a side of the processing region 10a. Thereby, it is possible for a plate-shaped member 51 to cause an exhaust gas to flow along the surface 51d on a side of the processing region 10a smoothly and it is possible to prevent or reduce degradation of an exhaust characteristic even through it has the plate-shaped member 51. Additionally, any surface treatment may be provided as long as a kinetic frictional resistance is deceased.

Furthermore, at least one of an arrangement intervals and angles of an oblique parts of the plurality of plate-shaped members 51 may be adjusted in such a manner that a conductance of a part of the exhaust region 10b with a low exhaust characteristic is greater than that of a part with a high exhaust characteristic. For example, as illustrated in FIG. 1, in the chamber 10 according to an embodiment, the mounting table 11 is arranged at a center thereof and the exhaust port 10e is singly provided at a position that is lower than a mounting surface of the mounting table 11 where a substrate W is mounted, around the mounting table 11. In such a case, an exhaust characteristic of the chamber 10 is non-uniform in a circumferential direction of the mounting table 11 where the exhaust characteristic is degraded with distance from the exhaust port 10e in a circumferential direction of the mounting table 11. Hence, the plurality of plate-shaped members 51 may be arranged in such a manner that interval thereof are increased with distance from the exhaust port 10e, around the mounting table 11, or may be arranged in such a manner that angles of an oblique parts relative to a vertical direction are decreased. Thereby, it is possible for the plurality of plate-shaped members 51 to reduce an exhaust non-uniformity of an exhaust characteristic in a circumferential direction of the mounting table 11.

As provided above, a substrate processing apparatus 1 according to an embodiment has a chamber 10 and a partition member 50. The chamber 10 is provided where an exhaust port 10e for exhausting a gas in an inside thereof is formed thereon and substrate processing for a substrate W is executed in the inside. The partition member 50 partitions the inside of the chamber 10 into a processing region 10a where the substrate processing is executed and an exhaust region 10b that leads to the exhaust port 10e. The partition member 50 is configured to include a plurality of plate-shaped members 51. The plurality of plate-shaped members 51 are provided in such a manner that at least a part of each thereof is arranged obliquely at intervals in a side view from a side of a side surface of the chamber 10 and an upper end part 51a of each thereof is arranged so as to overlap with a lower end part of a plate-shaped member 51 that is adjacent thereto in a top view from an upper side of the chamber 10. Thereby, it is possible for a substrate processing apparatus 1 to prevent or reduce penetration of particles P that are generated in an exhaust region 10b into a processing region 10a and prevent or reduce degradation of an exhaust characteristic.

Furthermore, each of the plurality of plate-shaped members 51 is provided as a flat plate that is flat and a whole thereof is arranged so as to be oblique. Thereby, it is possible for a substrate processing apparatus 1 to prevent or reduce penetration of particles P that are generated in an exhaust region 10b into a processing region 10a and prevent or reduce degradation of an exhaust characteristic.

Furthermore, each of the plurality of plate-shaped members 51 is provided as a curved plate and a side of the processing region 10a is arranged so as to be more oblique than a side of the exhaust region 10b. Thereby, it is possible for a substrate processing apparatus 1 to prevent or reduce penetration of particles P that are generated in an exhaust region 10b into a processing region 10a and prevent or reduce degradation of an exhaust characteristic.

Furthermore, each of the plurality of plate-shaped members 51 is provided as a curved plate and a side of the exhaust region 10b is arranged so as to be more oblique than a side of the processing region 10a. Thereby, it is possible for a substrate processing apparatus 1 to prevent or reduce penetration of particles P that are generated in an exhaust region 10b into a processing region 10a and prevent or reduce degradation of an exhaust characteristic. Furthermore, it is possible for a substrate processing apparatus 1 to collect a deposition that is deposited by a gas that is included in an exhaust gas, on a side of a mounting table 11.

Furthermore, the plurality of plate-shaped members 51 include an absorption mechanism that absorbs a kinetic energy of particles P from a side of the exhaust region 10b, on surfaces 51c thereof on a side of the exhaust region 10b. Thereby, it is possible for a plate-shaped member 51 in a substrate processing apparatus 1 to prevent or reduce recoil of particles P on a surface 51c thereof on a side of an exhaust region 10b, so that it is possible to further prevent or reduce penetration of particles P into a processing region 10a.

Furthermore, a surface treatment that decreases a kinetic frictional resistance is applied to surfaces 51d of the plurality of plate-shaped members 51 on a side of the processing region 10a. Thereby, it is possible for a substrate processing apparatus 1 to cause an exhaust gas to flow smoothly.

Furthermore, at least one of arrangement intervals and angles of oblique parts of the plurality of plate-shaped members 51 is adjusted in such a manner that a conductance of a part of the exhaust region 10b with a low exhaust characteristic is greater than that of a part thereof with a high exhaust characteristic. Thereby, it is possible for a substrate processing apparatus 1 to reduce non-uniformity of an exhaust characteristic in a circumferential direction of a mounting table 11.

Furthermore, the chamber 10 is provided in such a manner that a mounting table 11 that mounts the substrate W thereon is arranged at a center thereof and the exhaust port 10e is singly provided at a position that is lower than a mounting surface of the mounting table 11 where the substrate W is mounted, around the mounting table 11. The plurality of plate-shaped members 51 are arranged on an upstream side of the exhaust port 10e relative to a flow of an exhaust gas to the exhaust port 10e, around the mounting table 11, and are arranged at an intervals that increases with a distance from the exhaust port 10e or are arranged in such a manner that angles of oblique parts thereof relative to a vertical direction are decreased. Thereby, it is possible for a substrate processing apparatus 1 to reduce non-uniformity of an exhaust characteristic in a circumferential direction of a mounting table 11.

Although an embodiment has been explained above, it should be considered that an embodiment that is disclosed herein is not limitative but is illustrative in any aspect. In fact, it is possible to implement an embodiment as described above in a wide variety of modes thereof. Furthermore, an embodiment as described above may be omitted, substituted, or modified in a wide variety of modes thereof without departing from what is claimed and an essence thereof.

For example, although a case where a substrate W is provided as a semiconductor wafer and substrate processing is provided as plasma processing has been explained as an example in an embodiment as described above, this is not limiting. A substrate may be any substrate such as a glass substrate. Substrate processing may be any processing as long as it is executed by exhausting an inside of the chamber 10.

Furthermore, although a case where a cylindrical space is formed inside the chamber 10 and a shape of the mounting table 11 is provided as a cylindrical shape has been explained as an example in an embodiment as described above, this is not limiting. A shape of the mounting table 11 may be provided as a rectangular shape and an inside of the chamber 10 may be a rectangular space.

Furthermore, although a case where the plurality of plate-shaped members 51 are arranged as the partition member 50 has been explained as an example in an embodiment as described above, this is not limiting. A plurality of members where a through-hole is formed into a spiral shape may be arranged as the partition member 50. For example, a plurality of members where a through-hole is formed into a spiral shape in upward and downward directions are arranged so as to surround a periphery of the mounting table 11 and execute partition into the processing region 10a and the exhaust region 10b. As a though-hole is provided with a spiral shape, the processing region 10a and the exhaust region 10b are provided in an invisible state thereof in a top view, so that it is possible to prevent or reduce penetrating of particles P that are generated in the exhaust region 10b into the processing region 10a. It is possible for an exhaust gas to flow through each through-hole, so that it is possible to prevent or reduce degradation of an exhaust characteristic.

According to the present disclosure, it is possible to prevent or reduce penetration of particles that are generated in an exhaust region into a processing region and prevent or reduce degradation of an exhaust characteristic.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a chamber where an exhaust port for exhausting a gas in an inside thereof is formed thereon and substrate processing for a substrate is executed in the inside; and
a partition member that partitions the inside of the chamber into a processing region where the substrate processing is executed and an exhaust region that leads to the exhaust port, wherein
the partition member is configured to include a plurality of plate-shaped members, and
the plurality of plate-shaped members are provided in such a manner that at least a part of each thereof is arranged obliquely at intervals in a side view from a side of a side surface of the chamber and an upper end part of each thereof is arranged to overlap with a lower end part of the plate-shaped member that is adjacent thereto in a top view from an upper side of the chamber.

2. The substrate processing apparatus according to claim 1, wherein
each of the plurality of plate-shaped members is provided as a flat plate that is flat and a whole thereof is arranged to be oblique.

3. The substrate processing apparatus according to claim 1, wherein
each of the plurality of plate-shaped members is provided as a curved plate and a side of the processing region is arranged to be more oblique than a side of the exhaust region.

4. The substrate processing apparatus according to claim 1, wherein
each of the plurality of plate-shaped members is provided as a curved plate and a side of the exhaust region is arranged to be more oblique than a side of the processing region.

5. The substrate processing apparatus according to claim 1, wherein
the plurality of plate-shaped members include an absorption mechanism that absorbs a kinetic energy of particles from a side of the exhaust region, on surfaces thereof on a side of the exhaust region.

6. The substrate processing apparatus according to claim 1, wherein
a surface treatment that decreases a kinetic frictional resistance is applied to surfaces of the plurality of plate-shaped members on a side of the processing region.

7. The substrate processing apparatus according to claim 1, wherein
at least one of arrangement intervals and angles of oblique parts of the plurality of plate-shaped members is adjusted in such a manner that a conductance of a part of the exhaust region with a low exhaust characteristic is greater than that of a part thereof with a high exhaust characteristic.

8. The substrate processing apparatus according to claim 1, wherein
the chamber is provided in such a manner that a mounting table that mounts the substrate thereon is arranged at a center thereof and the exhaust port is singly provided at a position that is lower than a mounting surface of the mounting table where the substrate is mounted, around the mounting table, and
the plurality of plate-shaped members are arranged on an upstream side of the exhaust port relative to a flow of an exhaust gas to the exhaust port, around the mounting table, and are arranged at intervals that increases with a distance from the exhaust port or are arranged in such a manner that angles of oblique parts thereof relative to a vertical direction are decreased.
